(19) United States
(12) Patent Application Publication
(10) Pub. No.: US 2004/0195207 A1
(43) Pub. Date: Oct. 7, 2004

(54) Substrate cleaning device and a method for manufacturing electronic devices

(75) Inventor: Hiroshi Tanaka, Hyogo (JP)

Correspondence Address: McDermott, Will & Emery, 600 13th Street, N.W., Washington, DC, 20005-3098, US

(73) Assignee: RENESAS TECHNOLOGY CORP.

(21) Appl. No.: 10/690,565

(22) Filed: Oct. 23, 2003

(30) Foreign Application Priority Data
Apr. 3, 2003 (JP) 2003-100703(P)

(51) Int. Cl. G01L 21/30; G01R 31/00

(52) U.S. Cl. 216/59

(57) ABSTRACT

In a substrate cleaning device, a substrate is held and is opposite to a plurality of heating/cooling components that can operate at different temperatures, the substrate and the heating/cooling components being separated to each other with a gap, which is filled with cleaning liquid. Chuck pins of resin with a low heat conductivity are used to hold the substrate, and the substrate is positioned such that it is not in contact with any component other than the chuck pins. In this way, the amount of etching can be adjusted for each portion of the substrate by controlling the temperature distribution on the substrate, thereby providing improved evenness of a surface within the plane of the substrate after a cleaning process.

### BACKGROUND OF THE INVENTION

1. Field of the Invention

The present invention relates to a substrate cleaning device used, for example, for a semiconductor, and a method for manufacturing electronic devices such as semiconductor devices.

2. Description of the Background Art

Conventional cleaning devices for semiconductor devices are often used for cleaning of films formed on a semiconductor substrate and for a cleaning process where a surface of the formed films is etched. In such cases, liquid or gas used for cleaning is continuously provided on the substrate (for example, see Japanese Patent Laying-Open No. 2000-277477 (FIG. 1, at page 4)).

However, when using such methods, in order to perform a cleaning process where a substrate is heated or cooled, heated or cooled liquid or gas is continuously provided to compensate for dissipated and absorbed heat. The flow of liquid or gas that is continuously provided is spread over the entire surface of the substrate. Thus, during etching of films formed on a substrate, etching is performed with a uniform thickness over the entire surface. For example, the thickness of films stacked on a substrate on its periphery can be different from that of films stacked on the substrate at its center. In such cases, conventional methods etch and remove an almost uniform thickness of a film throughout the plane, such that different film thicknesses after the treatment reflect the different thicknesses before the process. If, for example, contact holes are subsequently made, a non-uniform film thickness requires a greater amount of overetching in order to allow the holes to reach an underlying interconnection on the entire substrate plane which may cause decreased yield, due to penetration of a stopper film in the underlying interconnection.

### SUMMARY OF THE INVENTION

An object of the present invention is to overcome problems as described above, and more particularly, to provide a method for cleaning a substrate to provide a more uniform film thickness after a film stacked on a semiconductor substrate is etched.

A substrate cleaning device according to the present invention that achieves the objects mentioned above includes a plurality of heat sources, a temperature controller for heating and cooling the plurality of heat sources independently of each other, a substrate holder for disposing one surface of the heat sources and one surface of the substrate opposite to each other and with a gap therebetween, and a liquid filler for filling the gap with liquid.

According to the present invention, evenness within a plane of a substrate after a cleaning process can be improved by allowing at least two of a plurality of heating/cooling components, used for heating and cooling, to be set to operate at different temperatures, controlling the temperature distribution on a substrate to adjust the amount of etching performed on each portion of the substrate.

Further, temperature setting and temperature controlling can be performed for each of concentric circles by disposing a surface of the plurality of heating/cooling components that is opposite to the substrate along different concentric circles.

Also, a substrate can be cleaned by convection caused by a rotating movement by rotating the substrate holder about the center of the substrate and rotating said substrate at the same time.

Yet further, practically the same temperature from the heating/cooling devices can be transferred onto a liquid contact surface of the substrate by providing a plurality of chuck pins made of resin as a substrate holder and allowing the substrate to contact the chuck pins only.

Also, evenness within a plane of a substrate after a cleaning process can be improved by allowing at least two of a plurality of heating/cooling components used for heating and cooling to be set to operate at different temperatures for a cleaning process of the substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view of a semiconductor substrate cleaning device according to a first embodiment of the present invention.

FIGS. 2A and 2B are a plan view and a cross section, respectively, showing a form of heating/cooling components used in a semiconductor substrate cleaning device according to an embodiment of the present invention.

FIGS. 3A and 3B are a plan view and a cross section, respectively, showing a structure of a heating/cooling component used in the semiconductor substrate cleaning device according to the first embodiment of the present invention.

FIG. 4 is a schematic diagram of a film thickness distribution on a substrate, the substrate having been etched by the semiconductor substrate cleaning device according to the first embodiment of the present invention.

FIGS. 5A, 5B are plan views of other forms of heating/cooling components used in the semiconductor substrate cleaning device according to the first embodiment of the present invention.

### DESCRIPTION OF THE PREFERRED EMBODIMENTS

A first embodiment of the present invention will be described below. In the drawings, which will be referred to in connection with the present embodiment described below, the same or corresponding parts are referred to by the same numbers, and will not be described again.

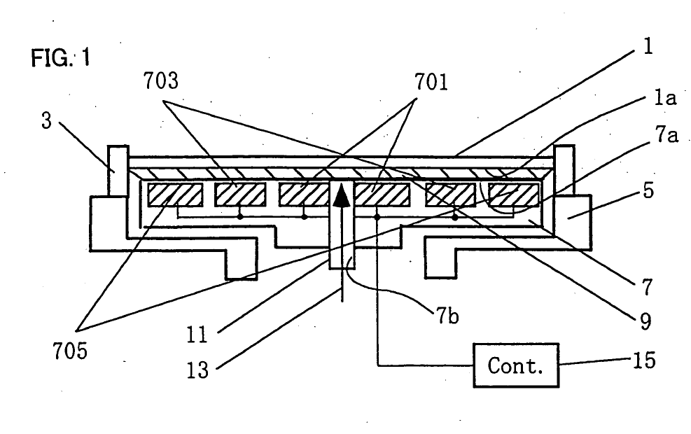

Now, referring to FIG. 1, a semiconductor substrate 1 is held by chuck pins 3 provided on a wafer holder 5 and is opposite to a heating/cooling portion 7, which implements the heat source of the present invention. Chuck pins 3 are used to pinch the substrate on its side.

Wafer holder 5 has a mechanism that provides a rotating movement about the center of substrate 1, and is used for rotating substrate 1 by this rotating movement at a prescribed speed. Wafer holder 5 is separated from a liquid filler 11 and heating/cooling portion 7 with a space therebetween, such that substrate 1 is rotated relative to heating/cooling portion 7.

Heating/cooling portion 7 has at least one plane 7a, and functions to heat and cool this plane 7a. Heating/cooling portion 7 is arranged such that plane 7a and one surface 1a of substrate 1 are opposite to each other and a prescribed gap 9 is provided between said plane 7a and one surface 1a of substrate 1. The distance provided by this gap 9 ranges from several hundred micrometers to several millimeters. Further, a through hole 7b is provided that extends vertically through the center of heating/cooling portion 7, and liquid filler 11 is disposed within this through hole 7b. Liquid filler 11 is a cylindrical component through which liquid 13 flows, and is used for filling with liquid 13 gap 9 between plane 7a of heating/cooling portion 7 and one plane 1a of substrate 1. Note that liquid 13 covers a variety of liquids including any chemical, solvent and pure water used for cleaning substrate 1. Thus, liquid 13 that is controlled in temperature is provided on one plane 1a of the substrate that faces wafer holder 5. Heating/cooling portion 7 has heating/cooling components 701, 703, 705; more particularly, each of heating/cooling components 701, 703, 705 is made of a Peltier device, for example.

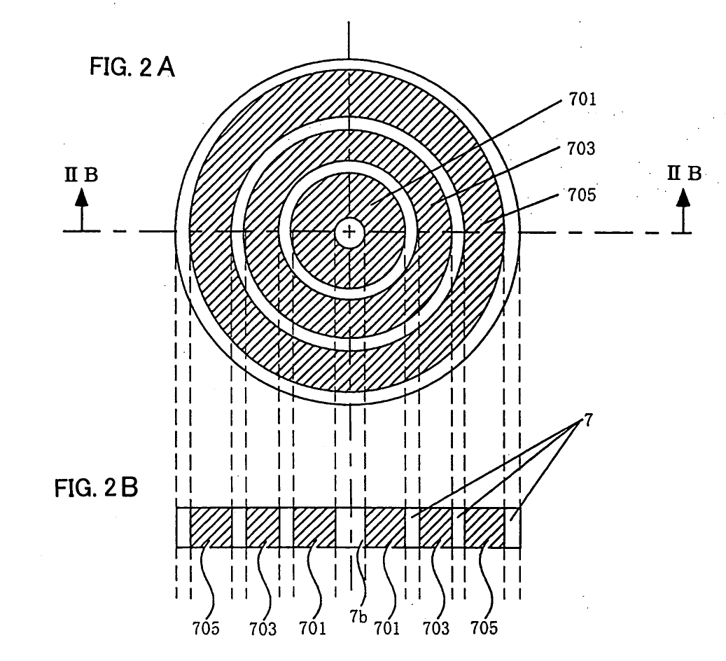

FIG. 2A is a plan view of heating/cooling components 701, 703, 705 shown in FIG. 1. FIG. 2B is a cross section of heating/cooling components 701, 703, 705 taken along the line IIB-IIB and is identical with the cross section of heating/cooling components 701, 703, 705 of FIG. 1.

Heating/cooling components 701, 703, 705 are embedded in heating/cooling portion 7 and separated from each other, and they are disposed along different concentric circles with their center being at the center of the plane of heating/cooling portion 7, and can be controlled in temperature independently of each other by means of temperature controller 15. Therefore, heating/cooling portion 7 can operate at different temperatures along the concentric circles that have their center at the center of the plane, and the liquid contact surface of semiconductor substrate 1 can be at different temperatures along the concentric circles via liquid 13 that fills gap 9.

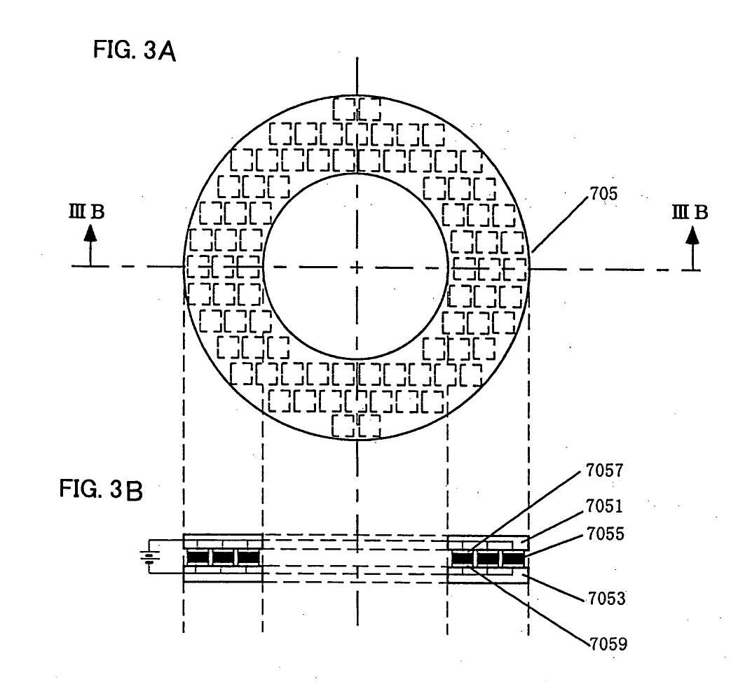

FIG. 3A is a plan view of a structure of heating/cooling component 705 of FIG. 1, and FIG. 3B is a cross section of heating/cooling component 705 taken along the line IIIB-IIIB, and is identical with the cross section of heating/cooling component 705 of FIG. 1.

Heating/cooling component 705 is constructed of a Peltier device and is structured such that a Peltier device is sandwiched by two disc-shaped ceramic plates with a hole at their center. The electrodes are shared by each Peltier device. When a voltage is applied between the common electrodes, each Peltier device generates heat on one side and absorbs heat on the other, thereby heating one ceramic plate while cooling the other. Reversing the polarity of the voltage switches the devices between heating and cooling. Heating/cooling components 701, 703 are similarly arranged.

Chuck pins 3 are placed on the upper end of wafer holder 5 and formed with resin, which has a heat conductivity lower than that of metal and the like and has a high water repellency. The resin is implemented by, for example, polyvinyl chloride (PVC), polychlorotrifluoroethylene (PCTFE). High repellency of chuck pins 3 allows liquid 13 to remain in gap 9 by means of surface tension of liquid 13. Moreover, since chuck pins 3 have a heat conductivity that is lower than that of metal and the like, they hardly affect the temperature distribution of substrate 1. Substrate 1 is in contact with chuck pins 3 only, and accordingly in no contact with any component of high heat conductivity.

Now, the operation of the above-mentioned cleaning device is described. Semiconductor substrate 1 is rotated at a prescribed speed by a rotating movement of wafer holder 5. At the same time, a required amount of liquid 13 is introduced to fill gap 9 between one plane of semiconductor substrate 1 and a plane of heating/cooling portion 7 by means of liquid filler 11. The required amount herein means an appropriate amount of liquid that fills up gap 9 but does not overflow the gap.

Then, the temperature of one plane 1a of the substrate in contact with liquid 13 that fills gap 9 (hereinafter referred to as “liquid contact surface temperature”) is increased or decreased to a prescribed degree via liquid 13 through a heating or cooling operation of heating/cooling portion 7. As mentioned above, gap 9 between heating/cooling portion 7 and semiconductor substrate 1 is very small, and a material with high heat conductivity is generally used as liquid 13, such that liquid 13 that fills this gap 9 is heated or cooled instantly by heating/cooling portion 7, and the liquid contact surface temperature on semiconductor substrate 1 immediately reaches the prescribed degree. Further, liquid 13 is not supplied continuously nor in a great amount, but is moved only by convection caused by the rotation of semiconductor substrate 1 after gap 9 is filled up, and can transfer practically the same temperature of heating/cooling portion 7 to the liquid contact surface of semiconductor substrate 1. One plane 1a of substrate 1 is then cleaned and etched at a prescribed liquid contact surface temperature.

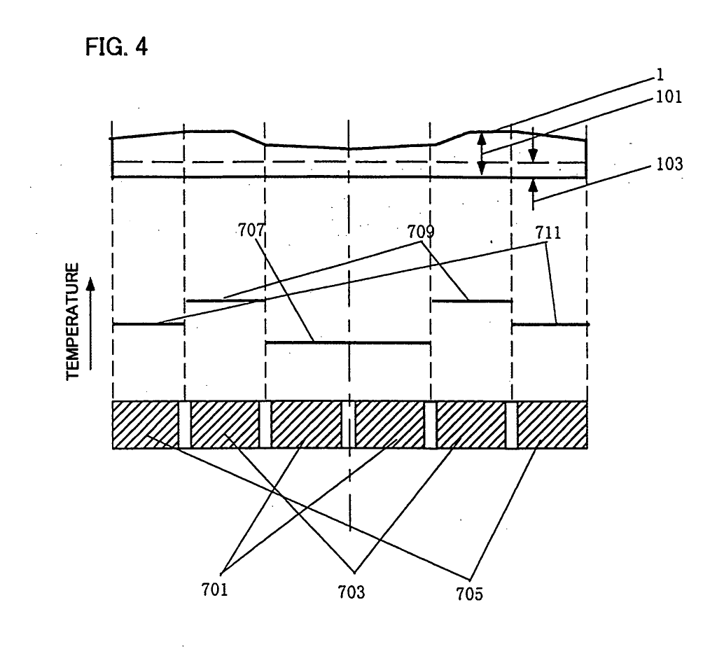

A film on a semiconductor substrate is often not formed with a uniform thickness due to a non-uniform reaction of a gas used to form a film on the substrate. Suppose, for example, that an initial film thickness 101 of a conductive film or insulator film formed on a substrate, as shown in FIG. 4, is smaller in an area near the center and periphery of the semiconductor substrate. A cleaning device according to the present invention is used to etch the semiconductor substrate such that the substrate has a flat surface with a film thickness 103 after the treatment. Accordingly, the surface must be made flat either by reducing the amount of etching for the area near the center and periphery, or increasing the amount of etching between the center and the periphery. Since the rate of etching is higher with a higher temperature, and is lower with a lower temperature, the amount of etching is controlled by controlling the temperature. According to the present invention, such control of the amount of etching can be achieved when a temperature setting 707 of heating/cooling component 701 corresponding to the area around the center and a temperature setting 711 of heating/cooling component 705 corresponding to the area near the periphery are lower than a temperature setting 709 of heating/cooling component 703 corresponding to the area between the center and periphery, thereby providing a target film thickness 103 that is more uniform after the treatment.

It should be noted that FIG. 4 shows an example with temperature settings being generally divided into three parts for convenience, but the present invention should not be limited thereto and the configuration is not limited to a concentric one. For example, a configuration of square components in an array achieves a similar effect as far as it has a structure with temperature settings and temperature control functions being independent of each other.

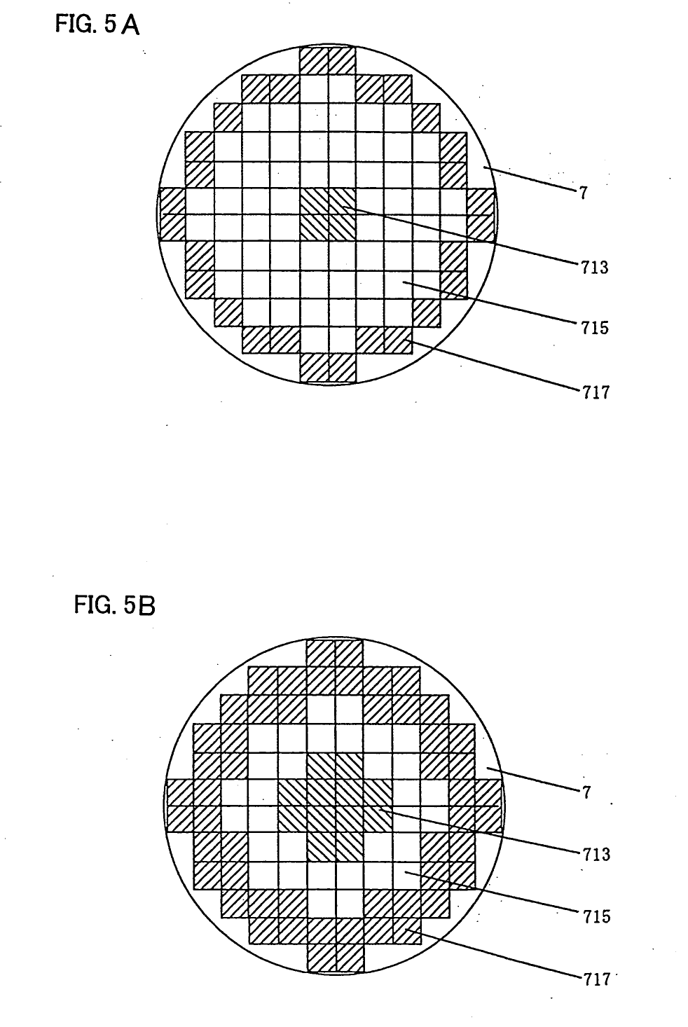

A heating/cooling component in an area near the periphery of a substrate, one in an area near the center and one between the periphery and center can each operate at different temperatures, corresponding to the condition of thickness distribution of a film upon its forming, by controlling the temperature of each of the heating/cooling components separately. FIG. 5A shows a plan view of heating/cooling portions where a region (hereinafter referred to as a “first temperature setting region”) 717 with a heating/cooling component near the periphery of the substrate being set to be at a first temperature, and a region (hereinafter a “third temperature setting region”) 713 with a heating/cooling component around the center being set to be at a third temperature, are relatively narrow, and a region (hereinafter a “second temperature setting region”) 715 with a heating/cooling component between the periphery and center being set to a second temperature is relatively wide. FIG. 5B shows heating/cooling portions where first temperature setting region 717 and third temperature setting region 713 are broader and second temperature setting region 715 is narrower than those of FIG. 5A. Thus, the temperature can be set more accurately according to the condition of thickness distribution of a film by controlling the temperature of square heating/cooling components disposed in an array separately.

Therefore, according to the first embodiment, the temperature distribution can be controlled on a plane of a semiconductor substrate by providing a plurality of temperature settings within the plane of the substrate for heating and cooling during a process of cleaning a semiconductor substrate, thereby providing improved evenness of the plane of the substrate after the cleaning process.

It should also be noted that, in the embodiment described above, a substrate is heated and cooled, when a cleaning process is performed, by heating/cooling components constructed of Peltier devices, but the present invention can perform the temperature setting for cooling only in order to suppress part of etching reaction, thereby controlling the temperature distribution on the substrate. Also, the temperature distribution on a substrate can be controlled by performing the temperature setting for heating only, in order to accelerate part of etching reaction. For temperature control with heating only, the heating component can be implemented by a normal heater.

It should further be noted that the present invention is not limited to a method for manufacturing semiconductor devices, but is applicable to a method for manufacturing electronic devices including the step of cleaning a substrate, for example manufacturing a liquid crystal display.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A substrate cleaning device comprising:
a plurality of heat sources, each used for heating or cooling;
temperature controller provided to control a temperature of said plurality of heat sources to allow said plurality of heat sources to be set at different temperatures;
substrate holder to hold a substrate being separated from said heat sources with a gap, and being opposite to said heat sources; and
liquid filler provided to fill said gap with liquid.

2. The substrate cleaning device of claim 1, wherein said plurality of heat sources each have a surface opposite to said substrate along a different concentric circle.

3. The substrate cleaning device of claim 1, wherein said substrate holder is rotated about a center of said substrate and causes said substrate to rotate.

4. The substrate cleaning device of claim 1, wherein said substrate holder is a plurality of chuck pins, and said substrate is in contact with said chuck pins only.

5. The substrate cleaning device of claim 1, wherein said heat sources include a Peltier device.

6. The substrate cleaning device of claim 4, wherein said chuck pins are formed of resin.

7. The substrate cleaning device of claim 6, wherein said resin includes polyvinyl chloride or polychlorotrifluoroethylene.

8. A method for manufacturing an electronic device comprising the step of etching a surface of a substrate using a substrate cleaning device including:
a plurality of heat sources, each used for heating or cooling;
temperature provided to control a temperature of said plurality of heat sources to allow said plurality of heat sources to be set at different temperatures;
substrate holder to hold a substrate, separated from said heat sources with a gap, and being opposite to said heat sources; and
liquid filler provided to fill said gap with liquid.
